(19) United States
(12) Patent Application Publication
(10) Pub. No.: US 2012/0081129 A1
(43) Pub. Date: Apr. 5, 2012

(54) TEST APPARATUS

(75) Inventor: Toshiyuki Negishi, Tokyo (JP)

(73) Assignee: ADVANTEST CORPORATION, Tokyo (JP)

(21) Appl. No.: 13/322,994

(22) PCT Filed: Jun. 1, 2010
(86) PCT No.: PCT/JP10/03653

§ 371 Date: Nov. 29, 2011

(30) Foreign Application Priority Data
Jun. 3, 2009 (JP) 2009-134263

(51) Int. Cl. G01R 27/28

(52) U.S. Cl. 324/612

(57) ABSTRACT

Delay circuits apply a delay to set and reset pulses, respectively. An RS flip-flop is set according to the set pulse that has passed through the set delay circuit, and is reset according to the reset pulse received from the reset delay circuit. A demultiplexer receives the reset pulse that has passed through the reset delay circuit. In a first state, the demultiplexer outputs the reset pulse to the reset terminal of the RS flip-flop. In a second state, the demultiplexer outputs the reset pulse signal to the reset delay circuit again, thereby forming a closed loop. A loop control unit counts the number of times a pulse is passed through the loop. When the number of passes through the closed loop reaches a predetermined value, the demultiplexer is set to the first state.

### CROSS-REFERENCE TO RELATED APPLICATIONS

This application is the U.S. National Stage of International Patent Application No. PCT/JP2010/003653 filed on Jun. 1, 2010, which claims priority to Japanese Patent Application No. 2009-134263 filed on Jun. 3, 2009, the disclosures of which are hereby incorporated by reference in their entireties.

### BACKGROUND OF THE INVENTION

1. Field of the Invention

The present invention relates to a test apparatus, and particularly to a TDR (Time Domain Reflectometry) technique for measuring the length of a transmission path that connects a device under test and a test apparatus.

2. Description of the Related Art

In order to test whether or not a semiconductor device such as memory, a CPU (Central Processing Unit), a GPU (Graphics Processing Unit), or various kinds of DSPs (Digital Signal Processors), has desired characteristics, a semiconductor test apparatus (which will also be referred to simply as the “test apparatus” hereafter) is employed. The test apparatus applies a predetermined test pattern to a semiconductor device (which will be referred to as the “DUT: Device Under Test” hereafter). Subsequently, the test apparatus receives a signal from the DUT, and compares the signal thus received with an expected value, so as to identify defective parts of the DUT, or to judge the quality of the DUT.

FIG. 1 is a block diagram which shows an example configuration of a test apparatus (memory tester) for memory. A test apparatus 1002 mainly includes a pattern generator PG, a timing generator TG, a waveform shaper FC, a driver DR, a timing comparator TC, and a logical comparison unit LC.

The pattern generator PG generates a data string (test pattern TP) to be supplied to the DUT 1 in units of a rate period T_{RATE}. Based upon the test pattern TP, the timing generator TG generates timing setting data TP which sets a timing at which a positive edge and a negative edge are to be set in an output signal Sout to be supplied to the DUT 1.

The waveform shaper FC receives the timing setting data TP, and generates an output signal FP, the value of which changes at a timing that corresponds to the timing setting data TP. The driver DR outputs the output signal Sout to the DUT 1 via a terminal P_{IO}.

The timing comparator TC receives a signal Sin output from the DUT 1, and latches the value of the signal Sin at a predetermined timing. For example, the timing comparator TC includes a pair of a level comparator LCP and a latch LL and a pair of a level comparator HCP and a latch HL. The level comparator LCP compares the signal Sin received from the DUT 1 with a lower threshold voltage VOL, and generates an SL signal which is set to high level (1) when Sin<VOL. The latch LL latches the SL signal at a timing at which an edge occurs in a strobe signal STRB. Furthermore, the level comparator HCP compares the signal Sin received from the DUT 1 with an upper threshold voltage VOH, and generates an SH signal which is set to high level (1) when Sin>VOH. The latch HL latches the SH signal at a timing of a strobe signal STRB.

For each test cycle, the logical comparison unit LC compares an output signal Q of the latch LL (HL) with an expected value EXP, and generates a pass/fail signal PASS/FAIL which indicates whether or not the output signal Q matches its expected value EXP.

The above is the schematic configuration of the test apparatus 1002.

Typically, with the test apparatus 1002, the internal timing is calibrated on the basis of the timing at the input/output terminal P_{IO}. The test apparatus 1002 is connected to the DUT 1 via a transmission path 3 arranged on a test fixture. Accordingly, the timing at the device terminal P_{DUT} does not match the timing at the input/output terminal P_{IO} of the test apparatus 1002. Thus, in order to calibrate the difference in timing between the device terminal P_{DUT} and the input/output terminal P_{IO} of the test apparatus 1002, the length of the transmission path 3 is measured using the TDR (Time Domain Reflectometry) method.

Description will be made regarding a summary of the TDR method. FIG. 2 is a time chart which shows a measurement principle used in the TDR method for measuring the length (electrical length) Tpd of the transmission path. Before the electrical length Tpd (which will be referred to as the “TDRX” hereafter) of the transmission path 3 is measured using the TDR method, the DUT 1 is detached from the test fixture. That is to say, the impedance of the DUT 1 side as viewed from the test apparatus 1002 is in the open state. In this state, the waveform shaper FC generates a signal FP having a predetermined pulse width (high level period) TDRPW and a predetermined off period (low level period) OFFTIME. The device terminal P_{DUT} side is in the open state, and accordingly, when the driver DR outputs the signal FP thus generated to the transmission path 3 via the input/output terminal P_{IO}, the signal FP thus output is completely returned by complete reflection. The voltage level of the signal Sin thus reflected is compared with a threshold voltage VOL1 (VOL2) so as to generate an SL signal. By measuring the pulse width of the SL signal, such an arrangement is capable of obtaining the electrical length TDRX of the transmission path 3.

FIG. 3 is a circuit diagram which shows an example configuration of a part of the test apparatus 1002 which is capable of measuring the length of the transmission path 3 using the TDR method. It should be noted that the test apparatus 1002 is shown in FIG. 3 for exemplary purpose only, and is not necessarily a known technique as of the filing date.

First, description will be made regarding the normal test operation. In the normal test operation, the TDR signal is negated (set to low level). The reference clock signal REFCLK is set to high level for each rate period T_{RATE}.

An AND gate A1 gates the reference clock signal REFCLK using a gate signal GATEET1. The AND gate A1 outputs a set pulse SP1. In the same way, an AND gate A2 gates the reference clock signal REFCLK using a gate signal GATEET2 so as to generate a reset pulse RP1.

The set pulse SP1 passes through an OR gate O1. Upon receiving a trailing edge (negative edge) of the set pulse SP1, a trailing edge pulser P1 generates a set pulse SP2 having a predetermined pulse width. In the same way, upon receiving a trailing edge of the reset pulse RP1 that passes through an OR gate O2, a trailing edge pulser P2 generates a reset pulse RP2 having a predetermined pulse width.

A set delay circuit 1012 receives timing setting data TP_{S} generated by the timing generator TG shown in FIG. 1, and applies a delay to the set pulse SP2 according to the timing setting data TP_{S}. In the same way, the set delay circuit 1012 receives timing setting data TP_{R} generated by the timing generator TG shown in FIG. 1, and applies a delay to the reset pulse RP2 according to the timing setting data TP_{R}.

The set pulse SP3 thus delayed is input to the set terminal (S) of an RS flip-flop FF1. The reset pulse RP3 thus delayed is input to the reset terminal (R) of the RS flip-flop FF1. That is to say, the timing at which a positive edge occurs in the output signal FP of the RS flip-flop FF1 and the timing at which a negative edge occurs in the output signal FP are controlled according to the values of the timing setting data TP_{S} and TP_{R}, respectively.

Description has been made above regarding the test operation. Next, description will be made regarding the operation for performing the TDR measurement. When the TDR measurement is performed, the TDR signal is asserted (set to high level). At a given timing, a loop start signal LOOPSTART is asserted (set to high level), and is injected to the OR gate O1. The loop start signal LOOPSTART passes through the trailing edge pulser P1 and the delay circuit 1012, and reaches the set terminal (S) of the RS flip-flop FF1. At this timing, the output FP of the RS flip-flop FF1 is set to high level.

The loop start signal LOOPSTART that passes through the delay circuit 1012 reaches the reset terminal (R) of the RS flip-flop FF1 via an AND gate A3, the OR gate O2, the trailing edge pulser P2, and a delay circuit 1014. At this timing, the output FP of the RS flip-flop FF1 is set to low level.

The delay circuits 1012 and 1014 each include a first-stage offset delay element OD (=8 ns) and a second-stage delay element VD (≦4 ns). When TDR measurement is performed, the delay circuit 1014 is connected in cascade to delay circuits provided as different respective channels, so as to provide a triple delay.

The period from the timing at which the RS flip-flop FF1 is set until a timing at which the RS flip-flop FF1 is reset corresponds to the pulse width TDRPW of the FP signal. Accordingly, the pulse width of the FP signal is determined according to the delay amount applied by the delay circuit 1014. The FP signal is output to the transmission path 3 via the driver DR, following which it is reflected, and subsequently reaches the comparator LCP. The SL signal again reaches the OR gate O1 on the set side via a trailing edge pulser P3, a pulse stretcher S4, and an AND gate A4. After a delay time set for the delay circuit 1012 has elapsed, the RS flip-flop FF1 is set, and the FP signal is set to high level again.

The output signal (SL signal) of the comparator LCP is also input to a frequency counter FONT. The frequency counter FONT measures the period during which the SL signal is set to high level. The electrical length TDRX is calculated based upon the count value CNT1 of the frequency counter FCNT.

Typical test apparatuses are required to have a performance for measuring the electrical length TDRX with an upper limit of approximately 10 ns. Furthermore, in order to operate such a test apparatus in a sure manner, such an arrangement requires the SL signal shown in the time chart in FIG. 2 to have a pulse width that is equal to or greater than a certain value Tmin (4 ns, which is the period of the reference clock signal REFCLK, for example).

Giving consideration to such requirements, the pulse width TDRPW of the FP signal and the off period OFFTIME are respectively required to satisfy the following relations.

TDRPW≧2×TDRX+Tmin

OFFTIME≧2×TDRX+4 ns

When TDRX=10 ns, and Tmin=4 ns, the requirements are represented by the following Expressions.

TDRPW≧24 ns

OFFTIME≧24 ns

As described above, the pulse width TDRPW of the FP signal corresponds to the delay amount applied by the delay circuit 1014. Thus, when the delay amount of a single delay stage applied by the offset delay element OD is set to a period (T_{RATE}×2) which is double the period of the reference clock signal REFCLK, and the delay amount of a single delay stage applied by the variable delay element VD is set to a period (T_{RATE}) which is equal to the period of the reference clock signal REFCLK, the overall delay amount applied by the delay circuit 1014 (i.e., the pulse width TDRPW) is represented by the following Expression (3).

3×(T_{RATE}×2+T_{RATE})=9×T_{RATE} (3)

When T_{RATE}=4 ns, TDRPW is 36 ns, and accordingly, the aforementioned requirement (1) is satisfied. The same can be said of the off period OFFTIME.

In recent years, the operating speed of a DUT 1 has been steadily increasing, leading to an increase in the operating speed of the test apparatus 1002. This means that there is an increase in the frequency of the reference clock signal REFCLK (i.e., reduction in the rate period T_{RATE}), leading to a reduction in the delay amount applied by the delay elements included in the test apparatus 1002.

For example, if the rate period T_{RATE} is reduced to 125 ps, the pulse width TDRPW calculated based upon Expression (3) is 1.125 ns. In this case, requirement (1) is not satisfied, leading to a problem in that the electrical length TDRX of the transmission path 3 cannot be measured.

### SUMMARY OF THE INVENTION

The present invention has been made in view of such a situation. Accordingly, it is an exemplary purpose of an embodiment of the present invention to provide a test apparatus which is capable of measuring the electrical length of the transmission path using the TDR method.

An embodiment of the present invention relates to a test apparatus. The test apparatus comprises: a set delay circuit configured to apply a delay to a set pulse; a reset delay circuit configured to apply a delay to a reset pulse; an RS flip-flop configured to be set according to the set pulse that has passed through the set delay circuit, and to be reset according to the reset pulse that has passed through the reset delay circuit; a driver configured to receive an output signal of the RS flip-flop, and to output the output signal thus received to a transmission path to which a device under test is connected; a demultiplexer configured to receive the reset pulse that has passed through the reset delay circuit, to output the reset pulse thus received to a reset terminal of the RS flip-flop in a first state, and to output the reset pulse thus received to the reset delay circuit again in a second state so as to form a closed loop including the reset delay circuit; a loop control unit configured to count the number of times a pulse is passed through the closed loop in the second state, and to switch the demultiplexer to the first state when the number of passes reaches a predetermined value; a level comparator configured to receive a signal from the transmission path, and to compare the signal thus received with a predetermined threshold voltage; a first frequency counter configured to measure a period in which an output signal of the level comparator is a predetermined level; and a pulser configured to generate a pulse that corresponds to the output signal of the level comparator when a TDR (Time Domain Reflectometry) measurement is performed, and to input the pulse thus generated to the set delay circuit again as the set pulse.

With such an embodiment, by controlling the number of times a pulse is passed through the closed loop, such an arrangement is capable of controlling the pulse width of the signal to be output to the transmission path.

Also, the loop control unit may comprise: a counter configured to count an edge of a signal that passes through the closed loop; and a comparison unit configured to compare the count value of the counter with a predetermined threshold value. Also, when the count value reaches the threshold value, the demultiplexer may be set to the first state.

Also, a test apparatus according to an embodiment may further comprise a second frequency counter configured to measure a propagation time through the closed loop. Also, the first frequency counter may be configured to operate as such a second frequency counter.

It is to be noted that any arbitrary combination or rearrangement of the above-described structural components and so forth is effective as and encompassed by the present embodiments.

Moreover, this summary of the invention does not necessarily describe all necessary features so that the invention may also be a sub-combination of these described features.

### BRIEF DESCRIPTION OF THE DRAWINGS

Embodiments will now be described, by way of example only, with reference to the accompanying drawings which are meant to be exemplary, not limiting, and wherein like elements are numbered alike in several Figures, in which:

FIG. 1 is a block diagram which shows an example configuration of a test apparatus (memory tester) for memory as proposed by the present applicant;

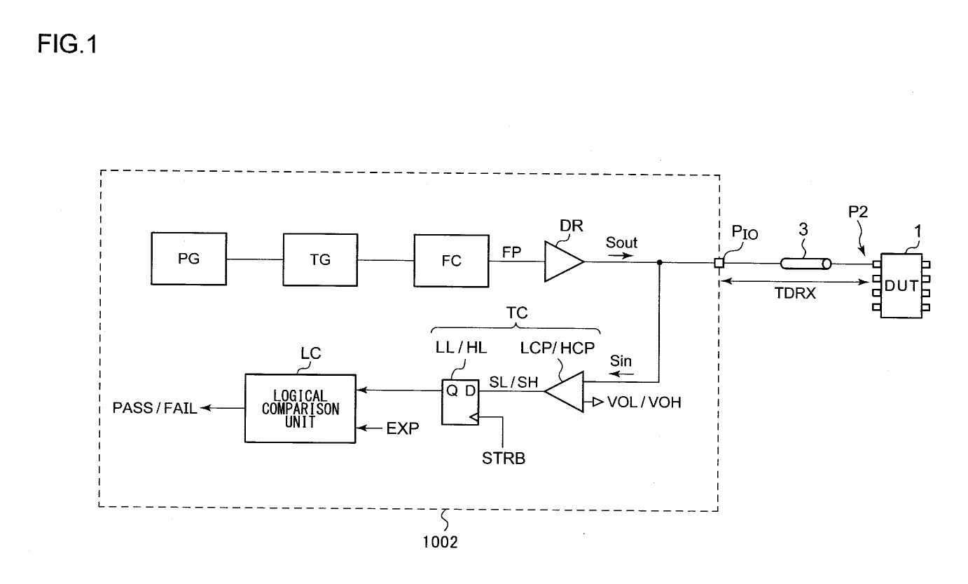

FIG. 2 is a time chart which shows a measurement principle for measuring the electrical length of the transmission path using the TDR method;

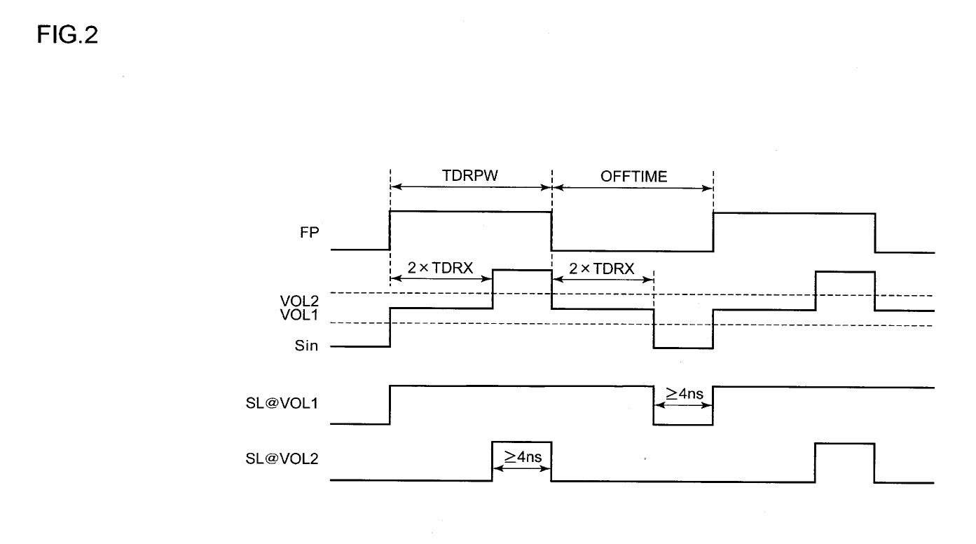

FIG. 3 is a circuit diagram which shows a part of an example configuration of a test apparatus which is capable of measuring the electrical length of the transmission path using the TDR method;

FIG. 4 is a circuit diagram which shows a configuration of a test apparatus according to an embodiment; and

FIG. 5 is a time chart which shows the TDR measurement operation of the test apparatus shown in FIG. 4.

### BEST MODE FOR CARRYING OUT THE INVENTION

Description will be made below regarding preferred embodiments according to the present invention with reference to the drawings. The same or similar components, members, and processes are denoted by the same reference numerals, and redundant description thereof will be omitted as appropriate. The embodiments have been described for exemplary purposes only, and are by no means intended to restrict the present invention. Also, it is not necessarily essential for the present invention that all the features or a combination thereof be provided as described in the embodiments.

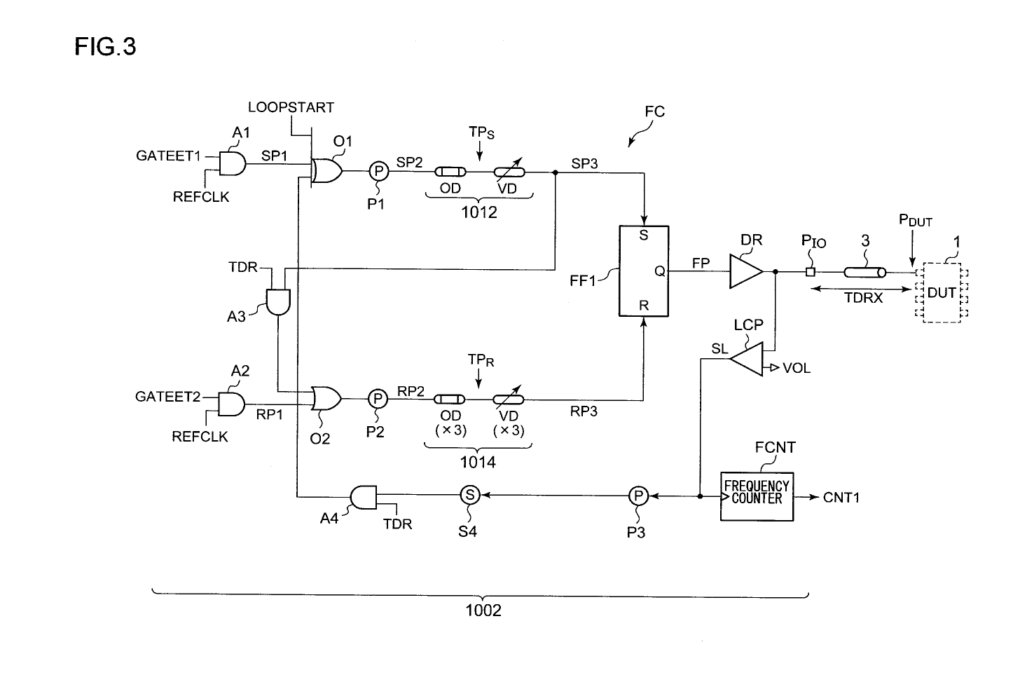

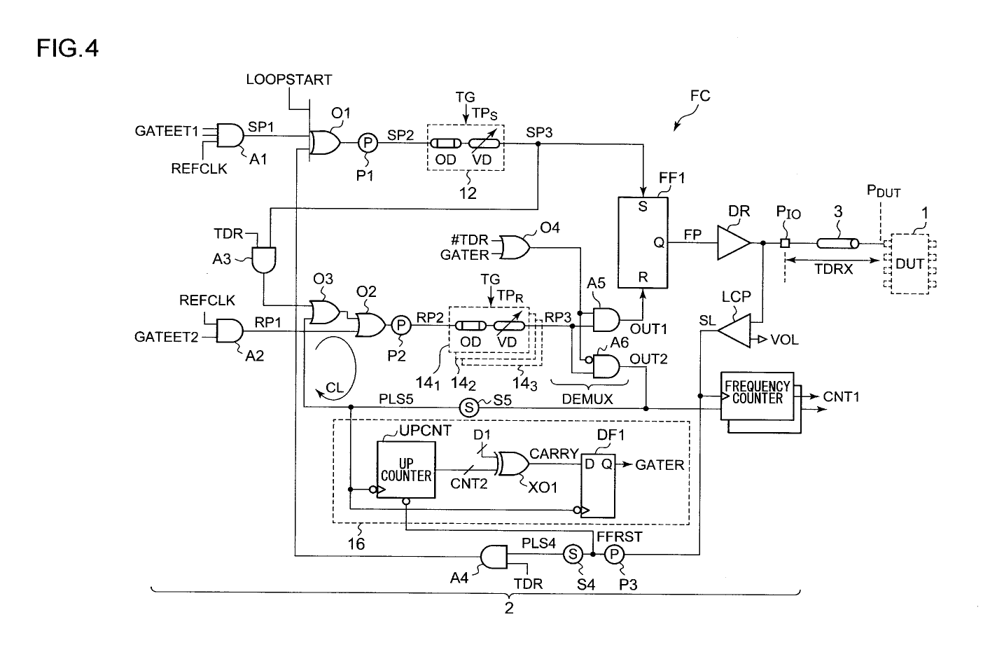

FIG. 4 is a circuit diagram which shows a configuration of a test apparatus 2 according to an embodiment. The same members as those shown in FIG. 3 are denoted by the same reference symbols, and redundant description thereof will be omitted. Separate description will be made below regarding a configuration of the test apparatus 2 for operating a normal test operation, and a configuration thereof for performing the TDR measurement.

### [Normal Test Operation]

As shown in FIG. 3, a TDR signal is negated (set to low level).

A set pulse SP1 that is synchronized to a test cycle (REFCLK) is generated by an AND gate A1. The set pulse SP1 is input to a set delay circuit 12 via an OR gate O1 and a trailing edge pulser P1. The set delay circuit 12 receives, from a timing generator TG, timing setting data TP_{S} which determines a timing at which a positive edge is to be generated in a test pattern to be supplied to the DUT 1. The set delay circuit 12 applies a delay that corresponds to the timing setting data TP_{S} to the set pulse SP1, and supplies the set pulse SP1 thus delayed to the set terminal (S) of an RS flip-flop FF1.

In the same way, a reset pulse RP1 that is synchronized to the test cycle is generated by an AND gate A2. By means of the reset delay circuit 14, the reset pulse RP1 thus generated is subjected to a delay that corresponds to the timing setting data TP_{R}. The reset pulse RP1 is input to the reset delay circuit 14 via OR gates O3 and O2 and a trailing edge pulser P2. The reset delay circuit 14 applies, to the reset pulse RP2, a delay that corresponds to the timing setting data TP_{R}.

An OR gate O4, and AND gates A5 and A6, function as a so-called demultiplexer (DEMUX). That is to say, the demultiplexer thus formed receives the reset pulse RP3, and outputs the reset pulse RP3 thus received to either one of the first output terminal OUT1 side or the second output terminal OUT2 side according to the signal values of two control signals #TDR (“#” indicates logical inversion) and GATER. Specifically, when at least one of the #TDR signal and the GATER signal is high level, the first output terminal OUT1 is selected. Otherwise, the second output terminal is selected.

In the normal test operation, #TDR is set to high level. Accordingly, in this state, the reset pulse RP3 is output from the first output terminal OUT1, and is supplied to the reset terminal (R) of the RS flip-flop FF1. That is to say, for each test cycle, the output signal (Q) of the RS flip-flop FF1 is set to high level (1) at a timing that corresponds to the timing setting data TP_{S}, and is set to low level (0) at a timing that corresponds to the TP_{R}. The output signal Q of the RS flip-flop FF1 is supplied to the DUT 1 via a driver DR.

The test apparatus 2 is capable of changing the timings (i.e., data period) at which a negative edge and a positive edge are generated in the output signal (Q) of the RS flip-flop FF1 in a real time manner (on the fly) by updating the timing setting data TP_{S} and TP_{R} for each test cycle.

The above is the description regarding the normal test operation. Next, description will be made regarding the configuration for the TDR measurement.

### [TDR Measurement]

When the TDR measurement is performed, the TDR signal is asserted (1). Furthermore, each of the set pulse SP1 and the reset pulse RP1 are fixedly set to low level.

A loop start signal LOOPSTART, which is switched to high level at a predetermined timing, is input to the OR gate O1. The trailing edge pulser P1 generates the set pulse SP2 using the loop start signal LOOPSTART that has passed through the OR gate O1. The set pulse SP2 is input to the set terminal (S) of the RS flip-flop FF1 via the set delay circuit 12. At a timing at which the set pulse SP3 reaches the set terminal of the RS flip-flop FF1, the output signal Q of the RS flip-flop FF1 transits to high level.

Furthermore, the set pulse SP3 that has passed through the set delay circuit 12 is input to the reset delay circuit 14 via an AND gate A3, the OR gates O3 and O2, and the trailing edge pulser P2.

FIG. 4 shows only a part of the test apparatus 2 that corresponds to a single input/output terminal P_{IO}. However, in practical use, the test apparatus includes multiple input/output terminals P_{IO} and the corresponding circuit units each having the same configuration.

The reset delay circuit 14 is configured such that, when the TDR measurement is performed, it is connected in cascade to different reset delay circuits 14 provided for respective circuit units that correspond to different terminals P_{IO}. For example, using the circuit units that correspond to two different input/output terminals, such an arrangement is capable of connecting the three reset delay circuits 14₁ through 14₃ in cascade.

The demultiplexer DEMUX receives an output signal of the final-stage reset delay circuit 14₃. The demultiplexer DEMUX selects one of the two output terminals OUT1 or OUT2 according to the control signals (#TDR and GATER).

A pulse stretcher S5 receives a signal from the second output terminal OUT2 of the demultiplexer DEMUX, and stretches the pulse width of this signal to a predetermined width. The output pulse PLS5 of the pulse stretcher S5 is returned to the OR gate O3.

With the test apparatus 2 shown in FIG. 4, during a period in which the demultiplexer DEMUX selects the second output terminal OUT2 (second state), the OR gates O3 and O2, the trailing edge pulser P2, the reset delay circuits 14₁ through 14₃, the AND gate A6 of the demultiplexer DEMUX, and the pulse stretcher S5 form a closed loop CL. During a period in which the demultiplexer DEMUX selects the first output terminal OUT1 (first state), the closed loop CL is disconnected.

A loop control unit 16 controls the state of the closed loop CL.

In the second state, the loop control unit 16 counts the number of times the reset pulse RP passes through the closed loop CL. When the number of passes through the loop reaches a predetermined value D1, the demultiplexer DEMUX is switched to the first state.

The loop control unit 16 includes an up counter UPCNT, an XOR gate XO1, and a D flip-flop DF1.

The up counter UPCNT counts the number of times the pulse PLS5 passes through the closed loop CL. FIG. 4 shows an arrangement in which the up counter UPCNT counts up in increments of negative edges of the output pulse PLS5 of the pulse stretcher S5. The count value CNT2 of the up counter UPCNT is compared with the predetermined threshold D1 by the XOR gate XO1. When the count value CNT2 reaches the threshold D1, the carry signal (CARRY) is asserted (set to high level). At a timing at which a negative edge occurs in the first output pulse of the trailing edge pulser P5 after the CARRY signal is asserted, the output signal (Q) of the D flip-flop DF1 is set to high level. The output signal (Q) of the D flip-flop DF1 is used as the GATER signal, which functions as a control signal for the demultiplexer DEMUX.

The output signal (SL signal) of a level comparator LCP is input to a trailing edge pulser P3. Upon detecting a negative edge in the SL signal, the trailing edge pulser P3 generates a pulse signal having a predetermined width. The output pulse FFRST of the trailing edge pulser P3 is supplied to the reset terminal (logical inverting terminal) of the up counter UPCNT. That is to say, the count value CNT2 of the up counter UPCNT is reset every time the SL signal transits to low level.

The pulse stretcher S4 receives the FFRST signal, and stretches the pulse width of the FFRST signal to a predetermined width. The output pulse PLS4 of the pulse stretcher S4 is input to the set terminal (S) of the RS flip-flop FF1 via an AND gate A4, the OR gate O1, the trailing edge pulser P1, and the set delay circuit 12.

A frequency counter FCNT measures a period in which the second output terminal OUT2 of the demultiplexer DEMUX is high level. The test apparatus 2 calculates the electrical length TDRX of the transmission path 3 based upon the count value CNT1. Furthermore, before the TDR measurement, the frequency counter FCNT is capable of measuring the signal propagation time T_{CL} with respect to the closed loop CL including the reset delay circuit 14.

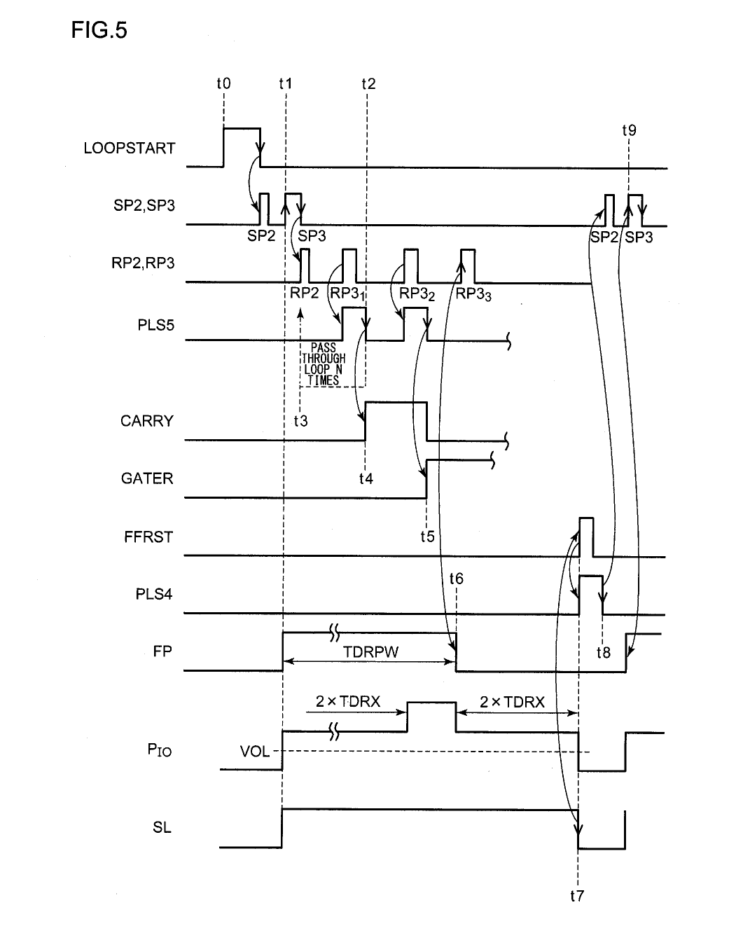

The above is the configuration of the test apparatus 2. Next, description will be made regarding the operation of the test apparatus 2 when the TDR measurement is performed. FIG. 5 is a time chart which shows the TDR measurement operation of the test apparatus 2 shown in FIG. 4.

At the time point t0, the loop start signal LOOPSTART is asserted, and the pulse SP2 transits to high level at a timing at which a negative edge occurs in the loop start signal LOOPSTART. The pulse SP2 passes through the trailing edge pulser P1 and the set delay circuit 12, thereby generating the pulse SP3. At a timing at which a positive edge occurs in the set pulse SP3 at the time point t1, the RS flip-flop FF1 is set, and accordingly, the output signal FP of the RS flip-flop FF1 is set to high level. At this timing t1, the electric potential at the input/output terminal P_{IO} rises, whereby the SL signal is set to high level.

At a timing at which a negative edge occurs in the set pulse SP3, the reset pulse RP2 is set to high level. The reset pulse RP2 passes through the trailing edge pulser P2 and the reset delay circuits 14₁ through 14₃, thereby generating the first reset pulse RP3₁.

At a timing at which the first reset pulse RP3₁ is generated, the GATER signal is low level. In this state, the closed loop CL is formed. Accordingly, the reset pulse RP3₁ is output to the pulse stretcher S5 side, thereby generating the pulse PLS5.

Upon detecting a negative edge in the pulse PLS5 at the time point t2, the up counter UPCNT counts up. The pulse PLS5 passes through the OR gates O3 and O3, and is input to the trailing edge pulser P2 again, thereby generating the next reset pulse RP2 (time point t3).

The test apparatus 2 repeats the processing performed at the time points t3 to t2 N times. Here, N represents an integer that corresponds to the threshold value D1. When the up counter UPCNT counts up N times, the CARRY signal is asserted (time point t4). Subsequently, at a timing at which a negative edge occurs in the next reset pulse RP3₂, the D flip-flop DF1 is clocked, whereby the output signal GATER is set to high level (time point t5).

When the GATER signal is set to high level, the demultiplexer DEMUX is connected to the first output terminal OUT1 side, and accordingly, the next reset pulse RP3₃ is input to the RS flip-flop FF1 (time point t6). At this timing, the FP signal is set to low level.

After the FP signal has transited to low level at the time point t6, when the round trip time (2×TDRX) required for a signal to make a round trip around the transmission path 3 elapses, i.e., at the time point t7, the input/output terminal P_{IO} is set to the ground electric potential (0 V). As a result, the SL signal is set to low level, and accordingly, the FFRST signal is generated by the trailing edge pulser P3. Subsequently, the pulse PLS4 is generated by the pulse stretcher S4. Upon receiving a negative edge of the FFRST signal, the up counter UPCNT is reset.

The pulse PLS4 is input to the trailing edge pulser P1 via the AND gate A4 and the OR gate O1. The trailing edge pulser P1 generates the set pulse SP2 using a negative edge of the pulse PLS4 (time point t8). Subsequently, at the timing at which a positive edge occurs in the set pulse SP3 (time point t9), the RS flip-flop FF1 is set, whereby the FP signal is set to high level again.

The test apparatus 2 repeats the processing performed at the time points t1 through t9.

The above is the TDR measurement operation of the test apparatus 2 according to the embodiment.

Next, description will be made regarding the advantages of the test apparatus 2.

With the test apparatus 2, in the TDR measurement operation, the reset pulse RP is passed through the closed loop CL, and the number of times the reset pulse RP is passed through the closed loop CL is controlled. Thus, such an arrangement is capable of controlling a timing at which the RS flip-flop FF1 is reset, i.e., the pulse width TDRPW of the FP signal.

That is to say, with the pulse propagation time required for a signal to pass through a single closed loop CL as T_{CL}, and the number of times the pulse is passed through the closed loop CL as N, the pulse width TDRPW of the FP signal is represented by T_{CK}×N.

The propagation time T_{CL} required for a signal to pass through the closed loop CL is represented by the sum total of the delay time applied by the reset delay circuit 14 and the propagation delay applied by the other elements.

For example, let us consider a case in which the offset delay OD and the variable delay VD applied by the reset delay circuit 14 are each equal to the rate period T_{RATE}, and the rate period T_{RATE} is set to 0.25 ps. In this case, the three-stage propagation delay applied by the reset delay circuit 14 is represented by (0.25+0.25)×3=1.5 ns. In a case in which the estimated delay time due to the other circuit elements is 0.5 ns, the propagation time with respect to the closed loop CL is represented by TL=1.5+0.5=2 ns. In this case, by setting N to 12, such an arrangement satisfies requirement (1) for the pulse width.

TDRPW≧24 ns (1)

That is to say, by suitably setting the number of passes N through the closed loop, such an arrangement is capable of generating a required pulse width even if the rate period T_{RATE} is reduced. Furthermore, in principle, by increasing the number of passes N through the closed loop, such an arrangement is capable of generating a pulse width TDRPW that is as long as desired. Thus, such an arrangement is capable of measuring a transmission path 3 having an electrical length that is greater than 10 ns.

Also, with the test apparatus 1002 according to a comparison technique shown in FIG. 3, the pulse width TDRPW is determined by the delay amount applied by the reset delay circuit 1014. Accordingly, there is a need to set the delay amount with high precision. Otherwise, when the pulse width TDRPW is estimated, there is a need to give consideration to irregularities in the delay amount. In contrast, with the test apparatus 2 shown in FIG. 4, the propagation time required for a signal to pass through the closed loop CL can be measured by the frequency counter FCNT. Thus, such an arrangement is capable of setting the pulse width TDRPW to a desired value even if there are irregularities in the delay amount applied by the reset delay circuit 14.

Description has been made with reference to FIG. 4 regarding an arrangement in which the multiple reset delay circuits 14 are connected in cascade. Also, the closed loop CL may be formed using a single reset delay circuit 14. With such an arrangement, the propagation time T_{CL} provided by the closed loop CL is reduced. However, by increasing the count number D2, such an arrangement is capable of providing the same pulse width TDRPW. Such a modification provides a signal propagation path in a simple manner.

Description has been made regarding the present invention with reference to the embodiments. However, the above-described embodiments show only the mechanisms and applications of the present invention for exemplary purposes only, and are by no means intended to be interpreted restrictively. Rather, various modifications and various changes in the layout can be made without departing from the spirit and scope of the present invention defined in appended claims.

1. A test apparatus comprising:
a set delay circuit configured to apply a delay to a set pulse;
a reset delay circuit configured to apply a delay to a reset pulse;
an RS flip-flop configured to be set according to the set pulse that has passed through the set delay circuit, and to be reset according to the reset pulse that has passed through the reset delay circuit;
a driver configured to receive an output signal of the RS flip-flop, and to output the output signal thus received to a transmission path to which a device under test is connected;
a demultiplexer configured to receive the reset pulse that has passed through the reset delay circuit, to output the reset pulse thus received to a reset terminal of the RS flip-flop in a first state, and to output the reset pulse thus received to the reset delay circuit again in a second state so as to form a closed loop including the reset delay circuit;
a loop control unit configured to count the number of times a pulse is passed through the closed loop in the second state, and to switch the demultiplexer to the first state when the number of passes reaches a predetermined value;
a level comparator configured to receive a signal from the transmission path, and to compare the signal thus received with a predetermined threshold voltage;
a first frequency counter configured to measure a period in which an output signal of the level comparator is a predetermined level; and
a pulser configured to generate a pulse that corresponds to the output signal of the level comparator when a TDR (Time Domain Reflectometry) measurement is performed, and to input the pulse thus generated to the set delay circuit again as the set pulse.

2. A test apparatus according to claim 1, wherein the loop control unit comprises:
a counter configured to count an edge of a signal that passes through the closed loop; and
a comparison unit configured to compare the count value of the counter with a predetermined threshold value,
and wherein, when the count value reaches the threshold value, the demultiplexer is set to the first state.

3. A test apparatus according to claim 1, further comprising a second frequency counter configured to measure a propagation time with respect to the closed loop.
